(19) United States
(12) Patent Application Publication
(10) Pub. No.: US 2025/0046587 A1
(43) Pub. Date: Feb. 6, 2025

(54) PLASMA DIAGNOSTIC DEVICE, AND SEMICONDUCTOR PROCESSING EQUIPMENT USING THE SAME

(71) Applicant: SAMSUNG ELECTRONICS CO., LTD., Suwon-si (KR)

(72) Inventors: Taehyun Kim, Suwon-si (KR); Chansoo Kang, Suwon-si (KR); Minju Kim, Suwon-si (KR); Daewon Kang, Suwon-si (KR); Dougyong Sung, Suwon-si (KR); Jungmo Yang, Suwon-si (KR); Sejin Oh, Suwon-si (KR)

(21) Appl. No.: 18/636,099

(22) Filed: Apr. 15, 2024

(30) Foreign Application Priority Data
Aug. 3, 2023 (KR) 10-2023-0101478

(51) Int. Cl. H01J 37/32; H01L 21/67

(52) U.S. Cl. CPC H01J 37/32917; H01L 21/67253; H01J 2237/24585

(57) ABSTRACT

The present disclosure relates to plasma diagnostic devices. An example plasma diagnostic device includes a pinhole through which a first optical signal passes, an optical device in which the first optical signal is incident and the first optical signal is converted into a second optical signal, a filter configured to filter the second optical signal and to output a third optical signal of a specific wavelength band, and a sensor configured to monitor a distribution of the first optical signal, the second optical signal, and the third optical signal.

### CROSS-REFERENCE TO RELATED APPLICATION

This application claims benefit of priority to Korean Patent Application No. 10-2023-0101478 filed on Aug. 3, 2023, in the Korean Intellectual Property Office, the disclosure of which is incorporated herein by reference in its entirety.

### BACKGROUND

The present disclosure relates to a plasma diagnostic device, and semiconductor processing equipment using the same.

In semiconductor processing equipment performing semiconductor processes such as deposition and etching using plasma, various methods have been proposed to measure characteristics of plasma. An electrical method of determining characteristics of plasma through an electrical manner using a probe, and an optical method of determining characteristics of plasma by measuring light emitted from plasma or absorbed by plasma have been proposed.

### SUMMARY

The present disclosure relates to plasma diagnostic devices, and semiconductor processing equipment using the same, which may verify the reliability of plasma generated by the semiconductor processing equipment and may be utilized to improve a yield of semiconductor processes, by installing the plasma diagnostic device in the semiconductor processing equipment, and collecting data required for plasma diagnosis with the plasma diagnostic device.

In general, according to some aspects, a plasma diagnostic device includes: a pinhole unit including a pinhole through which a first optical signal passes, wherein the first optical signal is naturally dispersed in an end of the pinhole; an optical unit in which the first optical signal is incident, and the first optical signal is converted into a second optical signal which is parallel light, and through which the second optical signal is emitted; a filter unit for filtering the second optical signal and outputting a third optical signal of a specific wavelength band; and a sensor unit for monitoring a distribution of the first optical signal through the third optical signal.

In general, according to some aspects, semiconductor processing equipment includes: a wafer; a chamber including a chamber wall and a wafer support on which the wafer is disposed; at least one view port installed on the chamber wall; at least one plasma diagnostic device installed in the view port in a center direction of the chamber; and a calculation unit connected to the plasma diagnostic device, wherein the plasma diagnostic device includes a pinhole unit on which an optical signal is incident, an optical unit for converting the optical signal naturally dispersed from an end of the pinhole unit into parallel light, a filter unit for filtering a specific wavelength band of the parallel light, and a sensor unit, and the calculation unit calculates an output of the sensor unit and outputs area-specific information of the wafer of plasma generated in a space inside the chamber.

In general, according to some aspects, semiconductor processing equipment includes: a wafer; a chamber including a chamber wall and a wafer support on which the wafer is disposed; at least one view port installed on the chamber wall; at least one plasma diagnostic device installed in the at least one view port in a center direction of the chamber; and a calculation unit connected to the at least one plasma diagnostic device, wherein the at least one plasma diagnostic device includes a pinhole unit, an optical unit, a filter unit, and a sensor unit, the pinhole unit emits a first optical signal to the optical unit, the optical unit emits a second optical signal obtained by converting the first optical signal into parallel light, the filter unit emits a third optical signal obtained by filtering a specific wavelength band of the second optical signal, and the sensor unit transmits raw data obtained by capturing the third optical signal to the calculation unit, the raw data includes first raw data obtained by filtering a first specific wavelength band of the second optical signal by the filter unit and second raw data obtained by filtering a second specific wavelength band of the second optical signal by the filter unit, and the calculation unit diagnoses plasma using the first raw data and the second raw data.

In general, according to some aspects, a plasma diagnostic device configured to collect data to determine the characteristics of plasma is installed in semiconductor processing equipment in which semiconductor processes are performed, thereby diagnosing plasma. The plasma diagnostic device includes an optical unit and a filter unit, and filters an optical signal converted into parallel light by the optical unit to a specific wavelength band, thereby improving the performance of the plasma diagnostic device.

Advantages and effects of the present application are not limited to the foregoing content and may be more easily understood in the process of describing some example implementations of the present disclosure.

### BRIEF DESCRIPTION OF THE DRAWINGS

The above and other aspects, features, and advantages of the present disclosure will be more clearly understood from the following detailed description, taken in conjunction with the accompanying drawings.

FIG. 1 is a view illustrating an example of a system.

FIG. 2 is a view schematically illustrating an example of a semiconductor process system.

FIG. 3 is a view schematically illustrating an example of semiconductor processing equipment.

FIG. 4 is a view schematically illustrating an example of semiconductor process monitoring equipment.

FIG. 5 is a view illustrating an example of a plasma diagnostic device.

FIGS. 6 to 8 are views illustrating an example of an optical unit.

FIGS. 9 to 11 are views illustrating another example of an optical unit.

FIGS. 12 to 17 are views schematically illustrating an upper surface of an example of semiconductor process monitoring equipment.

FIG. 18 is a flowchart illustrating an example of a plasma diagnosis process.

FIG. 19 is a flowchart illustrating another example of a plasma diagnosis process.

### DETAILED DESCRIPTION

Hereinafter, example implementations of the present disclosure will be described with reference to the accompanying drawings.

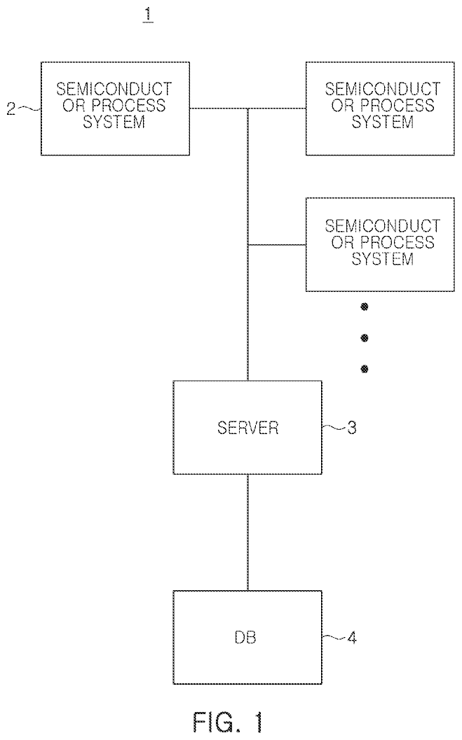

FIG. 1 is a view illustrating an example of a system.

Referring to FIG. 1, a system 1 performs various diagnosis and monitoring of plasma that directly affects the results of a semiconductor process. Specifically, the system 1 of the present disclosure diagnoses a plasma state by installing plasma diagnostic device including an optical unit and a filter unit.

In some implementations, the plasma diagnostic device may be included in a semiconductor process system 2 and may be installed in a chamber of the semiconductor processing equipment for performing a semiconductor process. Specifically, the plasma diagnostic device may be installed in a view port included in a chamber wall. The plasma diagnostic device may include a pin hole and may diagnose plasma through an optical signal incident through the view port and the pin hole.

In some implementations, data collected by the plasma diagnostic device may be transmitted to a server 3, and the server 3 may diagnose plasma characteristics generated inside a chamber based on data received from the plasma diagnostic device. For example, light distribution generated in plasma may be determined using the data collected by the plasma diagnostic device, from which the plasma distribution according to a position inside the chamber may be diagnosed. The server 3 may transmit at least one of data received from the plasma diagnostic device and plasma diagnosis results to a data base 4 (DB). The DB 4 may store information received from the server 3 and may transmit information requested by the server 3 to the server 3.

In some implementations, the semiconductor process system 2 may include semiconductor processing equipment. The semiconductor processing equipment may include a chamber, an electrostatic chuck installed in a space inside the chamber, a gas supply unit for supplying at least one of a source gas and a reaction gas, a power supply unit for supplying bias power to an electrode installed in the space inside the chamber, and a controller for controlling the power supply unit, the gas supply unit and the electrostatic chuck.

In some implementations, after the plasma diagnostic device is installed in the view port, the controller may control the power supply unit to generate plasma in the space inside the chamber and supply the bias power to an electrode, and the controller control the gas supply unit and supply at least one of the source gas and the reaction gas. Furthermore, the controller may control the gas supply unit, the power supply unit, and the electrostatic chuck using the data obtained from the plasma by the plasma diagnostic device.

While the gas supply unit supplies at least one of the source gas and the reaction gas to the space inside the chamber, the power supply unit may supply the bias power to an electrode installed in the space inside the chamber, and in this case, plasma may be generated. For example, the plasma may be installed in the space inside the chamber and may be formed in a space above the electrostatic chuck on which a wafer is settled. When the plasma is generated, a plasma light signal may be generated in a process of absorbing and emitting energy. The plasma light signal may be scattered more effectively at a specific wavelength depending on plasma distribution. Accordingly, plasma dispersion may be diagnosed by analyzing the specific wavelength of the plasma light signal.

In this case, the plasma optical signal may be extracted from a specific wavelength band. A central wavelength at which the filter unit included in the plasma diagnostic device filters the plasma optical signal may vary depending on an angle at which the plasma optical signal is incident on the filter unit. When an incident angle is not perpendicular to the filter unit, a wavelength band different from a target wavelength may be filtered, which may deteriorate performance of diagnosing plasma from the plasma optical signal. The plasma diagnostic device includes an optical unit, and the optical unit may convert a plasma light signal into parallel light. Accordingly, an incidence angle of the plasma optical signal incident on the filter unit may be maintained vertically, and the plasma optical signal at the specific wavelength band to be extracted into the filter unit may be input into the sensor unit, thereby improving the performance of the plasma diagnostic device.

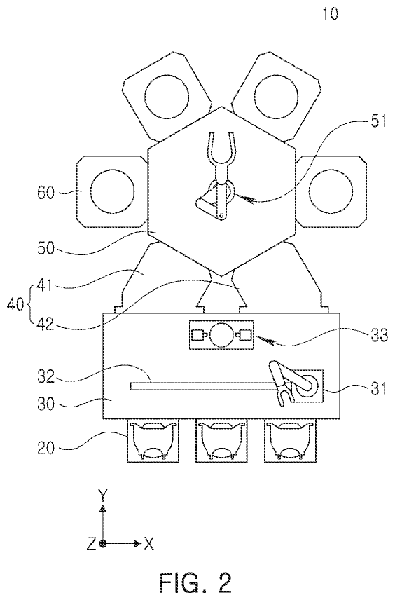

FIG. 2 is a view schematically illustrating an example of a semiconductor process system.

Referring to FIG. 2, a semiconductor process system 10 includes wafer transfer equipment 30, a load lock chamber 40, a transfer chamber 50, and a plurality of semiconductor processing equipment 60. For example, the wafer transfer equipment 30 receives a wafer through a container such as a FOUP 20 inside a line in which the semiconductor process system 10 is installed. The wafer transfer equipment 30 transfers the wafer received through the FOUP 20 to the load lock chamber 40, or receives the wafer on which the semiconductor process has been completed in the semiconductor processing equipment 60 from the load lock chamber 40 and store the wafer in the FOUP 20.

The wafer transfer equipment 30 may include a wafer transfer robot 31 having an arm capable of holding a wafer, a rail portion 32 for transferring the wafer transfer robot 31, and an aligner 33 for aligning the wafer. Assuming an operation of transferring a wafer from the FOUP 20 to the load lock chamber 40, the wafer transfer robot 31 may take out the wafer stored in the FOUP 20 and place the wafer on the aligner 33. The aligner 33 may rotate the wafer and align the wafer in one predetermined direction. When wafer alignment is completed in the aligner 33, the wafer transfer robot 31 may remove the wafer from the aligner 33 and transfer the wafer to the load lock chamber 40.

The load lock chamber 40 may be connected to the wafer transfer equipment 30, and may include a loading chamber 41 in which wafers brought into the semiconductor processing equipment 60 to perform a semiconductor process temporarily stay, and an unloading chamber 42 in which wafers taken out from the semiconductor processing equipment 60 after the process is completed temporarily stay. When the wafers aligned in the aligner 33 are brought into the loading chamber 41, an interior of the loading chamber 41 may be depressurized to prevent external contaminants from entering the loading chamber 41.

The load lock chamber 40 may be connected to the transfer chamber 50, and a plurality of semiconductor processing equipment 60 may be connected around the transfer chamber 50. A wafer transfer robot 51 may be disposed in the transfer chamber 50 to transfer wafers between the load lock chamber 40 and the plurality of semiconductor processing equipment 60. The wafer transfer robot 31 of the wafer transfer equipment 30 may be referred to as a first wafer transfer robot, and the wafer transfer robot 51 of the transfer chamber 50 may be referred to as a second wafer transfer robot.

Each of the plurality of semiconductor processing equipment 60 may perform a semiconductor process on a wafer. For example, the semiconductor process performed by the plurality of semiconductor processing equipment 60 may include a deposition process, an etching process, an exposure process, an annealing process, a polishing process, and an ion implantation process.

In order to perform at least some of the above-mentioned semiconductor processes, plasma may be formed inside at least one of the plurality of semiconductor processing equipment 60. The plasma may be formed on wafers, masks, display mother substrates, and the like, which are targets subject to the semiconductor process, and the distribution or yield of the semiconductor process may vary depending on how the plasma is formed. Accordingly, when the semiconductor process is actually performed in the semiconductor processing equipment 60, an operation of diagnosing and analyzing the characteristics of the formed plasma may be performed simultaneously.

In some implementations, the characteristics of the plasma formed in the semiconductor processing equipment 60 may be diagnosed by installing plasma diagnostic device in a view port included in the semiconductor processing equipment 60. For example, the plasma diagnostic device may diagnose the distribution of plasma formed inside a chamber using plasma light signals.

The plasma diagnostic device includes a pinhole unit, an optical unit, a filter unit, and a sensor unit. The optical unit may convert a plasma light signal passing through the view port and the pinhole into parallel light, and thus an incidence angle of the plasma light signal incident on the filter unit may be maintained vertically. Accordingly, the plasma optical signal at a specific target wavelength band may be input to the sensor unit, which may make it possible to accurately diagnose the plasma.

In this manner, by diagnosing the characteristics of plasma using the plasma diagnostic device and controlling the semiconductor processing equipment 60 using the diagnostic results, the distribution of the semiconductor process may be improved or the yield of the semiconductor process may be improved.

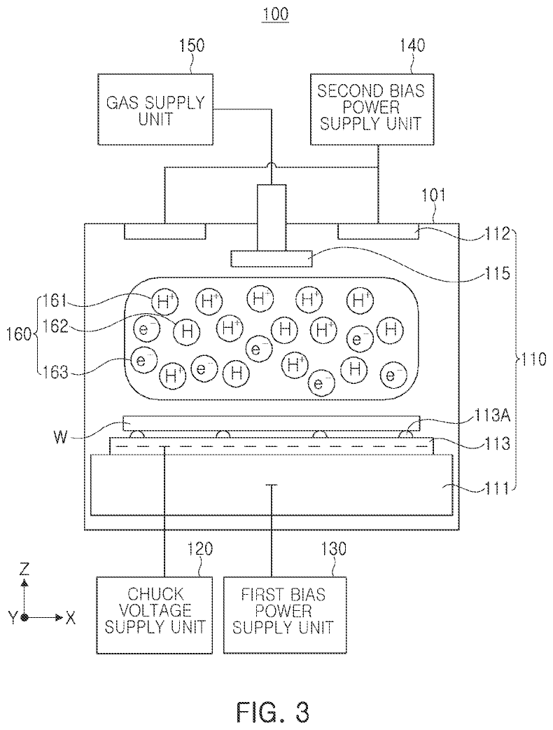

FIG. 3 is a view schematically illustrating an example of semiconductor processing equipment.

Semiconductor processing equipment 100 is equipment for performing a semiconductor process using plasma. The semiconductor processing equipment 100 includes a chamber 110, a chuck voltage supply unit 120, a first bias power supply unit 130, a second bias power supply unit 140, and a gas supply unit 150.

The chamber 110 includes a housing 101, a first bias electrode 111, a second bias electrode 112, an electrostatic chuck 113, and a gas flow path 115. A process target to be subject to a semiconductor process is settled on the electrostatic chuck 113. In an example implementation illustrated in FIG. 3, the process target is illustrated as a wafer W, but the process target may be changed to a display mother substrate, a mask, and the lie.

As illustrated in FIG. 3, a plurality of protrusions 113A having a protrusion shape are formed on an upper surface of the electrostatic chuck 113. The wafer W is settled on the protrusion 113A, and accordingly, a space is formed between the upper surface of the electrostatic chuck 113 and the wafer W. For example, the space between the upper surface of the electrostatic chuck 113 and the wafer W is filled with helium gas for the purpose of cooling the wafer W.

In some implementations, the wafer W may be fixed on the electrostatic chuck 113 by coulomb force generated from a chuck voltage supplied to the electrostatic chuck 113 by the chuck voltage supply unit 120. For example, the chuck voltage supply unit 120 may supply the chuck voltage to the electrostatic chuck 113 in the form of constant voltage, and the chuck voltage may have a magnitude of hundreds to thousands of volts.

A plasma gas may be introduced through the gas flow path 115 to perform the semiconductor process. The first bias power supply unit 130 may supply a first bias power to the first bias electrode 111 disposed below the electrostatic chuck 113, and the second bias power supply unit 140 may supply a second bias power to the second bias electrode 112 disposed above the electrostatic chuck 113. Each of the first bias power supply unit 130 and the second bias power supply unit 140 may include a radio frequency (RF) power source for supplying the bias power.

A plasma 160 including ions 161, radicals 162, and electrons 163 of a reaction gas may be generated in a space above the wafer W by the first bias power and the second bias power, and due to the plasma, the reaction gas may be activated and reactivity thereof may be increased. For example, when the semiconductor processing equipment 100 is etching equipment, the ions 161, the radicals 162 and the electrons 163 of the reaction gas may be accelerated to the wafer W by the first bias power supplied to the first bias electrode 111 by the first bias power supply unit 130. At least some of the semiconductor substrates or layers included in the wafer W may be dry-etched by the ions 161, the radicals 162, and the electrons 163 of the reactive gas.

In some implementations, when performing the etching process and the deposition process using the plasma 160, the plasma diagnostic device may be installed in the semiconductor processing equipment and the plasma 160 may be generated. The plasma diagnostic device may obtain data required for analyzing the characteristics of the plasma 160, and, for example, may detect a plasma optical signal at a specific wavelength band among the plasma optical signals generated from the plasma 160. The data obtained by the plasma diagnostic device may be used to analyze characteristics such as distribution of the plasma 160.

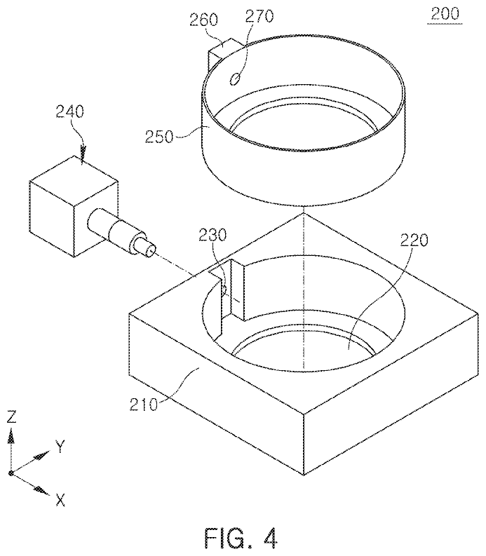

FIG. 4 is a view schematically illustrating an example of semiconductor process monitoring equipment.

Semiconductor process monitoring equipment 200 is installed inside semiconductor processing equipment. The semiconductor process monitoring equipment 200 includes a chamber body 210, a wafer support 220, plasma diagnostic device 240, a chamber wall 250, and a view port 260.

The chamber body 210 may be formed to include an accommodating space capable of accommodating process materials therein, and, for example, a cylindrical accommodating space may be formed inside the chamber body 210. A wafer support 220 may be formed on a bottom surface of the chamber body 210, and a wafer that may be used in a manufacturing process of a semiconductor device and a display device may be disposed on the wafer support 220. For example, the wafer may be disposed on the wafer support 220.

Plasma for performing a semiconductor process may be generated in a space inside the chamber body 210. For example, an etching process, a deposition process, and the like, may be performed by the plasma formed within the chamber body 210.

The chamber wall 250 may be formed in the chamber body 210 and may have a shape corresponding to the accommodation space in the chamber body 210. For example, an internal surface of the chamber wall 250 may be formed in a cylindrical shape to have substantially the same light reflectance. The chamber wall 250 may be formed to be in contact with an internal surface of the chamber body 210. Furthermore, the chamber wall 250 may be fixed into the chamber body 210 so as to come into contact with the internal surface of the chamber body 210. Furthermore, the chamber wall 250 may be fixed into the chamber body 210 to prevent shaking thereof when the plasma diagnostic device 240 monitors an interior of the chamber body 210.

The view port 260 may be formed on one side wall of the chamber wall 250, and at least one view port 260 may be formed. In an example implementation illustrated in FIG. 4, one view port 260 may be formed on one side wall of the chamber wall 250. The view port 260 may include a view port hole 270 for confirming a process progress state or a distribution state of process materials inside the chamber body 210. For example, the view port hole 270 may be formed to penetrate through one side wall of the chamber wall 250 and may be formed in a position arranged in line with a chamber body hole 230 included in the chamber body 210. The view port 260 may be formed in various shapes, and may be formed in a circular shape as illustrated in an example implementation illustrated in FIG. 4. A window may be installed inside the view port 260, and an internal space and an external space of the chamber wall 250 may be blocked from each other by the window.

The semiconductor process monitoring equipment 200 may include at least one plasma diagnostic device 240. The plasma diagnostic device 240 may include a pinhole unit, an optical unit, a filter unit, and a sensor unit. The plasma diagnostic device 240 may be installed in the view port 260 to be oriented towards a central portion of the chamber. In some implementations, the plasma diagnostic device 240 may be disposed outside the chamber wall 250. A portion of the plasma diagnostic device 240 may be inserted into the chamber body hole 230 and the view port hole 270. For example, the pinhole unit may be inserted into the chamber body hole 230 and the view port hole 270. In some implementations, the pinhole unit and the optical unit may be installed inside the chamber wall 250, and the filter unit and the sensor unit may be installed outside the chamber wall 250.

In some implementations, the plasma diagnostic device 240 may diagnose plasma formed in the chamber wall 250 using a plasma light signal incident through the view port 260. For example, the plasma light signal generated in the chamber wall 250 may pass through the pinhole unit and may be incident on the plasma diagnostic device 240. The optical unit may convert the plasma light signal into the parallel light, and accordingly, the plasma light signal may be incident perpendicularly to the filter unit. An incidence angle of the plasma light signal with respect to the filter unit may be maintained at a value close to verticality to improve the accuracy of filtering a specific wavelength band required by the filter unit, thereby improving plasma diagnosis performance of the plasma diagnostic device 240.

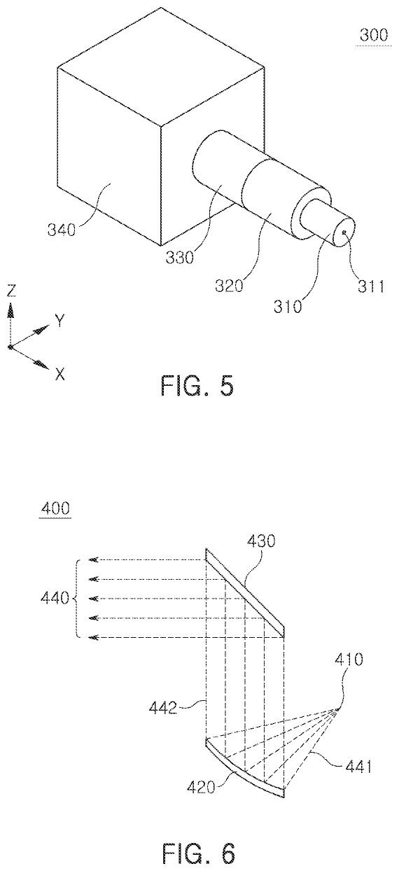

FIG. 5 is a view illustrating an example of a plasma diagnostic device.

In some implementations, plasma diagnostic device 300 is installed in a view port. As illustrated in FIG. 5, the plasma diagnostic device 300 includes a pinhole unit 310, an optical unit 320, a filter unit 330, and a sensor unit 340. In some implementations, the plasma diagnostic device 300 is disposed in the following order: the pinhole unit 310, the optical unit 320, the filter unit 330, and the sensor unit 340.

The pinhole unit 310 may be inserted in the view port or disposed in a chamber wall. The pinhole unit 310 may include a pinhole 311. For example, the pinhole 311 may have a circular shape penetrating through an interior of the pinhole unit 310. The pinhole 311 may allow data generated inside the chamber wall to be introduced into the plasma diagnostic device 300. In some implementations, the data generated inside the chamber wall may be a plasma light signal. For example, the plasma optical signal passing through the pinhole 311 may be naturally dispersed from an end of the pinhole 311 coming into contact with the optical unit 320, which may correspond to a first optical signal.

The optical unit 320 may convert the dispersed plasma light signal into parallel light and make the parallel light incident on the filter unit 330. In some implementations, the first optical signal may be incident on the optical unit 320, and the optical unit 320 may convert the first optical signal into a second optical signal, which is parallel light, and may emit the second optical signal. In some implementations, the optical unit 320 may include an off-axis parabolic mirror or a collimation lens. For example, the optical unit 320 may further include a relay lens and/or a plane mirror. In an example implementation illustrated in FIG. 5, a length of the optical unit 320 in an X-axis direction may be identical to a length of the filter unit 330, but unlike this, the length of the optical unit 320 may be different from the length of the filter unit 330. For example, when the optical unit 320 includes a relay lens, the length of the optical unit 320 may be longer than the length of the filter unit 330.

The filter unit 330 may filter the parallel light incident from the optical unit 320. In order to diagnose plasma from a plasma optical signal, only a specific wavelength must be extracted, and in some implementations, the filter unit 330 may filter a specific wavelength band. In other words, the second optical signal may be incident on the filter unit 330, and the filter unit 330 may emit a third optical signal obtained by filtering a specific wavelength band of the second optical signal. For example, the filter unit 330 may include a narrow band pass filter. Specifically, the filter unit 330 may include a tunable filter, and may change a set wavelength with fast switching speed. Accordingly, various wavelengths may be extracted in a short period of time, thereby improving the diagnostic performance of the plasma diagnostic device 300.

The sensor unit 340 may output monitoring results on a process state inside the chamber. In some implementations, a plasma optical signal at a specific wavelength band filtered by the filter unit 330 may be input to the sensor unit 340, and the sensor unit 340 may output monitoring results with respect to the plasma optical signal received from the filter unit 330. The sensor unit 340 may output raw data indicating distribution of plasma light signals in the chamber for each position. For example, the raw data may indicate the distribution of each position of the plasma optical signals in a direction, perpendicular to an upper surface of the wafer, based on a first direction in parallel with the upper surface of the wafer.

The plasma diagnostic device 300 may be connected to a calculation unit, and the calculation unit may be included in a semiconductor process system. In some implementations, the calculation unit may perform an operation of converting the raw data transmitted by the sensor unit 340, and the calculation unit may output the converted data after the calculation is completed. For example, the converted data may indicate the distribution of plasma for each wafer position in a second direction, parallel to the upper surface of the wafer and perpendicular to the first direction, based on the first direction in parallel with the upper surface of the wafer. In this case, Abel Transformation or Phillips-Tikhonov Transformation (PT Transformation) may be used. As compared to the Abel Transformation, the PT Transformation may have higher accuracy for noise and limited field of view areas.

Semiconductor processing equipment may include a communication circuit, and the calculation unit may use the communication circuit to transmit calculation results to external equipment. Through the communication circuit, a request for the calculation results may be received from the external equipment, or the calculation results of the calculation unit may be transmitted to the external equipment. In this case, the external equipment may be the server 3 of the example implementation illustrated in FIG. 1. The communication circuit may communicate with the external equipment in various ways, such as wireless or wired communication.

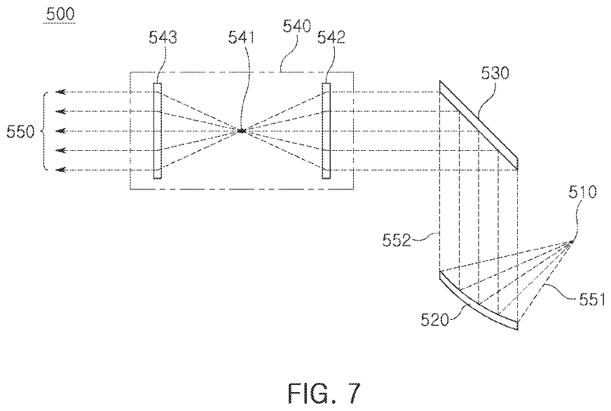

In some implementations, the plasma diagnostic device 300 may be installed in the view port inside the semiconductor processing equipment, and may collect data for diagnosing characteristics of the plasma in a state in which the plasma is generated inside the semiconductor processing equipment. In this case, the data may be collected using the plasma light signal flowing into the pinhole 311. The characteristics of the plasma generated inside the semiconductor processing equipment may be diagnosed using the collected data, and the semiconductor processing equipment may be controlled based on the diagnosis results of the plasma characteristics, thereby improving the distribution or yield of the semiconductor process. FIGS. 6 to 8 are views illustrating an example of an optical unit.

Optical units 400, 500 and 600 convert plasma optical signals 440, 550 and 660 into parallel light, and the plasma optical signals 440, 550 and 660 are divided into first optical signals 441, 551 and 661 and second optical signals 442, 552, and 662. The optical units 400, 500, and 600 are included in plasma diagnostic device and are disposed between a pinhole unit and a filter unit. Specifically, the optical units 400, 500 and 600 are disposed inside or outside a chamber wall. In some implementations, the optical units 400, 500 and 600 include off-axis parabolic mirrors 420, 520 and 620 and plane mirrors 430, 530 and 630.

According to the implementations illustrated in FIGS. 6 to 8, the off-axis parabolic mirrors 420, 520, and 620 may be disposed adjacently to ends 410, 510 and 610 of the pinhole unit. The first optical signals 441, 551 and 661 may be incident on the optical units 400, 500 and 600 by passing through the pinhole unit of the plasma diagnostic device. The first optical signals 441, 551 and 661 may be incident from the ends 410, 510 and 610 of the pinhole unit to interiors of the optical units 400, 500 and 600. Specifically, the first optical signals 441, 551 and 661 may be naturally dispersed from the ends 410, 510 and 610 of the pinhole unit and may proceed toward the interiors of the optical units 400, 500 and 600. The off-axis parabolic mirrors 420, 520 and 620 may reflect the first optical signals 441, 551 and 661 to emit second optical signals 442, 552 and 662. In this case, the second optical signals 442, 552 and 662 may be parallel light.

According to example implementations illustrated in FIGS. 6 to 8, the optical units 400, 500 and 600 may include plane mirrors 430, 530 and 630, but may not include the plane mirrors 430, 530, and 630, unlike the illustration. The plane mirrors 430, 530 and 630 may change a movement direction of the second optical signals 442, 552 and 662 reflected by the off-axis parabolic mirrors 420, 520 and 620. For example, the movement direction of the second optical signals 442, 552 and 662 reflected by the plane mirrors 430, 530 and 630 may be perpendicular to the existing movement direction. By including the plane mirrors 430, 530 and 630, the movement direction of the second optical signals 442, 552 and 662 may be appropriately adjusted to prevent one axis of the optical units 400, 500 and 600 from being elongated. Accordingly, the plasma diagnostic device may be efficiently installed in a limited space inside the chamber.

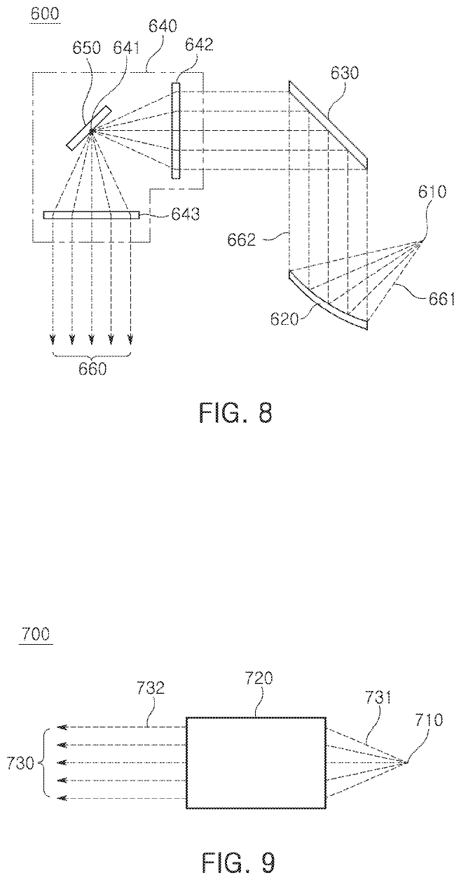

According to example implementations illustrated in FIGS. 7 and 8, the optical units 500 and 600 may include relay lenses 540 and 640. The relay lenses 540 and 640 may extend a movement distance of the second optical signals 552 and 662 reflected from the plane mirrors 530 and 630. In example implementations illustrated in FIGS. 7 and 8, the relay lenses 540 and 640 may include first lenses 542 and 642 and second lenses 543 and 643. The first lenses 542 and 642 may be disposed in positions on which the second optical signals 552 and 662 are incident, and the second lenses 543 and 643 may be disposed in positions from which the second optical signals 552 and 662 are radiated. The second optical signals 552 and 662 passing through the first lenses 542 and 642 may be collected at convergence points 541 and 641 and then incident on the second lenses 543 and 643, and the second optical signals 552 and 662 passing through the second lenses may be parallel light. However, the structure of the relay lenses 540 and 640 is not limited thereto, and may include at least two or more lenses.

With an increase in a temperature of the sensor unit, the sensor unit may have a characteristic that the signal to noise (SNR) decreases, and with an increase in noise, the reliability of the plasma diagnosis result may decrease. While the semiconductor process is in progress, the space inside the chamber may be maintained at a high temperature, and accordingly, the sensor unit may be affected by a high temperature environment inside the chamber. In some implementations, as the relay lenses 540 and 640 may be included in the optical units 500 and 600, a distance between a central portion of the chamber and the sensor unit may be extended, and performance degradation of the sensor unit may be prevented.

According to an example implementation illustrated in FIG. 8, the relay lens 640 may include a plane mirror 650. The plane mirror 650 may be disposed at the convergence point 641 of the relay lens 640, thus changing the movement direction of the second optical signal 662 inside the relay lens 640. As the plane mirror 650 is included therein, it may be possible to properly adjust the movement direction of the second optical signal 662 inside the relay lens 640 and prevent one axis of the optical unit 600 from being elongated. Accordingly, the plasma diagnostic device may be efficiently installed in the limited space inside the chamber.

In order to accurately diagnose the plasma generated inside the chamber, the plasma optical signal may need to be filtered in a desired wavelength band. However, even if the same plasma light signal is incident on the filter unit, a filtered central wavelength may change depending on the incidence angle. Accordingly, in order to maintain the incidence angle of the plasma light signal incident on the filter unit vertically, the plasma diagnostic device may include optical units 400, 500 and 600. The optical units 400, 500 and 600 may be included to maintain the incidence angle of the plasma optical signal with respect to the filter unit at a value close to verticality, thereby improving the accuracy of plasma diagnosis.

FIGS. 9 to 11 are views illustrating another example of an optical unit.

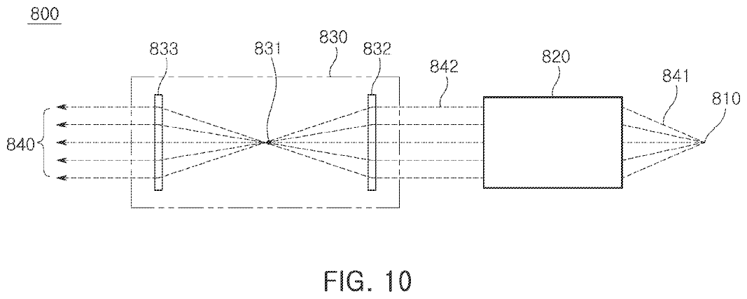

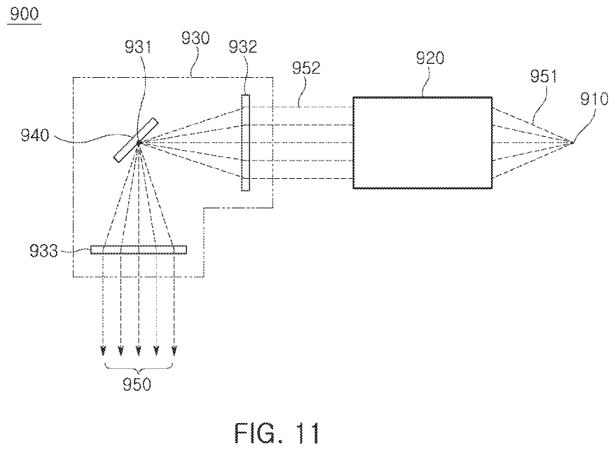

According to example implementations illustrated in FIGS. 9 to 11, optical units 700, 800 and 900 include collimation lenses 720, 820 and 920. According to example implementations illustrated in FIGS. 10 and 11, the optical units 800 and 900 include relay lenses 830 and 930, and according to an example implementation illustrated in FIG. 11, the optical units 900 includes a plane mirror 940 disposed at a convergence point 931 of the relay lens 930. As compared to FIGS. 6 to 8, there is a difference in configuration in which the off-axis parabolic mirror is replaced with the collimation lenses 720, 820 and 920, and specific implementations of FIGS. 9 to 11 may be similar to those described in FIGS. 6 to 8.

The optical units 700, 800 and 900 may convert plasma optical signals 730, 840 and 950 into parallel light, and the plasma optical signals 730, 840 and 950 may be divided into first optical signals 731, 841, and 951 and second optical signals 732, 842 and 952. The optical units 700, 800, and 900 may be included in plasma diagnostic device and may be disposed between a pinhole unit and a filter unit. Specifically, the optical units 700, 800 and 900 may be disposed inside or outside a chamber wall.

According to example implementations illustrated in FIGS. 9 to 11, the first optical signals 731, 841 and 951 may be naturally dispersed from ends 710, 810 and 910 of the pinhole unit and may be advanced into the optical units 400, 500 and 600. The first optical signals 731, 841 and 951 may be incident on the collimation lenses 720, 820 and 920, and the second optical signals 732, 842, and 952 obtained by refracting the first optical signals 731, 841 and 951 may be emitted. In this case, the second optical signals 732, 842, and 952 may be parallel light.

As in the example implementations illustrated in FIGS. 6 to 8, the plasma diagnostic device using the optical units 700, 800 and 900 including off-axis parabolic mirrors 420, 520 and 620 may have a relatively narrow angle of view. In some implementations, the off-axis parabolic mirrors 420, 520 and 620 may be replaced with the collimation lenses 720, 820 and 920 illustrated in FIGS. 9 to 11 to compensate for the narrow angle of view. The off-axis parabolic mirrors 420, 520 and 620 may be replaced with the collimation lenses 720, 820 and 920, thereby implementing the plasma diagnostic device having a relatively wide viewing angle.

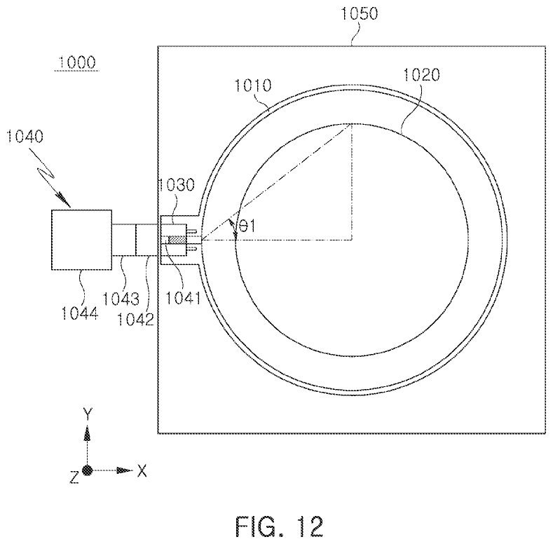

FIGS. 12 to 17 are views schematically illustrating an upper surface of an example of semiconductor process monitoring equipment.

Semiconductor process monitoring equipment 1000, 1100, 1200, 1300, 1400 and 1500 include chamber bodies 1050, 1150, 1250, 1350, 1470 and 1570, chamber walls 1010, 1110, 1210, 1310, 1410 and 1510, wafers 1020, 1120, 1220, 1320, 1420 and 1520, view ports 1030, 1130, 1230, 1330, 1430, 1440, 1530 and 1540, and plasma diagnostic device 1040, 1140, 1240, 1340, 1450, 1460, 1550 and 1560.

According to example implementations illustrated in FIGS. 12 to 17, the chamber walls 1010, 1110, 1210, 1310, 1410 and 1510 are formed inside the chamber bodies 1050, 1150, 1250, 1350, 1470 and 1570. The wafers 1020, 1120, 1220, 1320, 1420 and 1520 are disposed on a wafer support formed on a bottom surface of the chamber bodies 1050, 1150, 1250, 1350, 1470 and 1570.

The view ports 1030, 1130, 1230, 1330, 1430, 1440, 1530 and 1540 may include holes for confirming a state of performing processes within the chamber bodies 1050, 1150, 1250, 1350, 1470 and 1570. For example, the holes included in the view ports 1030, 1130, 1230, 1330, 1430, 1440, 1530 and 1540 may be formed to penetrate through one side wall of the chamber walls 1010, 1110, 1210, 1310, 1410 and 1510, and a window may be included inside the view ports 1030, 1130, 1230, 1330, 1430, 1440, 1530 and 1540.

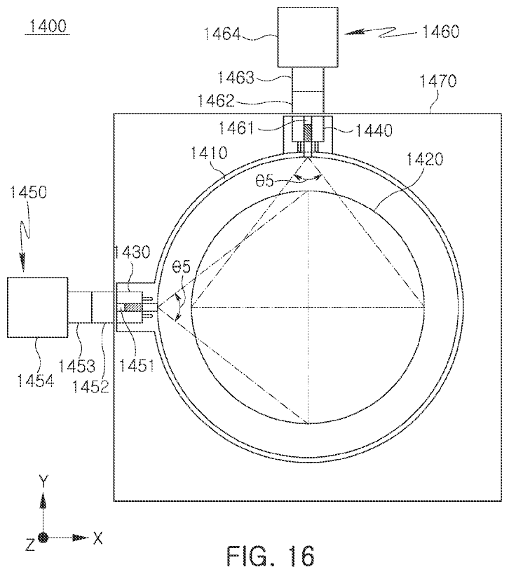

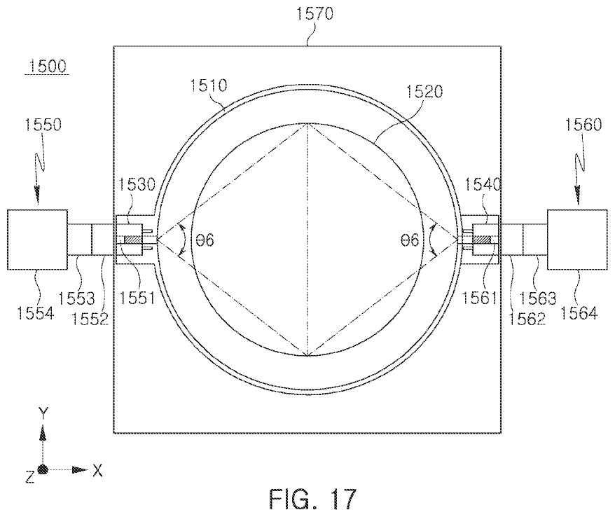

The view ports 1030, 1130, 1230, 1330, 1430, 1440, 1530 and 1540 may be formed on one side wall of the chamber walls 1010, 1110, 1210, 1310, 1410 and 1510, and at least one of the view ports 1030, 1130, 1230, 1330, 1430, 1440, 1530 and 1540 may be formed. In an example implementation illustrated in FIGS. 12 to 15, one view port 1030, 1130, 1230 or 1330 may be formed on one side wall of the chamber walls 1010, 1110, 1210 and 1310. In an example implementation illustrated in FIGS. 16 and 17, one view port 1430, 1440, 1530 or 1540 may be formed on each of the different side walls of the chamber walls 1410 and 1510. In other words, one chamber wall 1410 or 1510 may include two view ports. However, the number of view ports formed may be different from what is illustrated.

The plasma diagnostic device 1040, 1140, 1240, 1340, 1450, 1460, 1550 and 1560 may be installed in the view ports 1030, 1130, 1230, 1330, 1430, 1440, 1530 and 1540 to be oriented in a center direction of the chamber. The plasma diagnostic device 1040, 1140, 1240, 1340, 1450, 1460, 1550 and 1560 may include pinhole units 1041, 1141, 1241, 1341, 1451, 1461, 1551 and 1561, optical units 1042, 1142, 1242, 1342, 1452, 1462, 1552 and 1562, filter units 1043, 1143, 1243, 1343, 1453, 1463, 1553 and 1563, and sensor units 1044, 1144, 1244, 1344, 1454, 1464, 1554 and 1564.

Specific example implementations of the semiconductor process monitoring equipment 1000, 1100, 1200, 1300, 1400, 1500 and configurations thereof according to the example implementations illustrated in FIGS. 12 to 17 may be similar to those described in FIGS. 4 to 11.

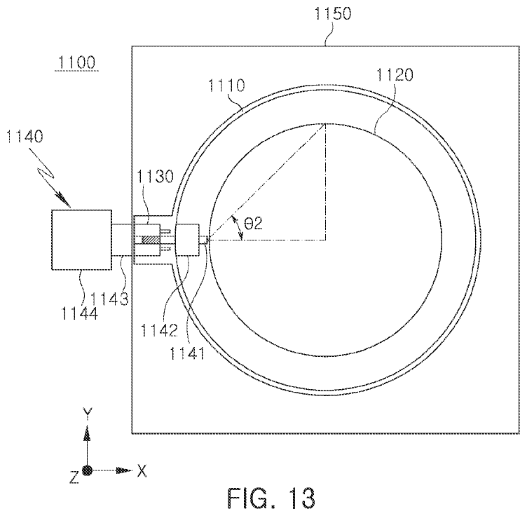

According to example implementations illustrated in FIGS. 12 and 13, the optical units 1042 and 1142 may include an off-axis parabolic mirror, and specific example implementations of the off-axis parabolic mirror may be similar to those described in FIGS. 6 to 8. The plasma diagnostic device 1040 illustrated in FIG. 12 may be disposed outside the chamber wall 1010 and have a first angle of view θ1. In the case of the plasma diagnostic device 1140 illustrated in FIG. 13, the pinhole unit 1141 and the optical unit 1142 may be disposed inside the chamber wall 1110, and the filter unit 1143 and the sensor unit 1144 may be disposed outside the chamber wall 1110. In this case, the plasma diagnostic device 1140 may have a second angle of view θ2. Unlike FIG. 12, since the pinhole unit 1141 in FIG. 13 may not be interfered by the view port 1130 and the chamber wall 1110, the second angle of view θ2 may be wider than the first angle of view θ1. Accordingly, the diagnostic accuracy of the plasma diagnostic device 1140 of FIG. 13 may be higher than that of the plasma diagnostic device 1040 of FIG. 12.

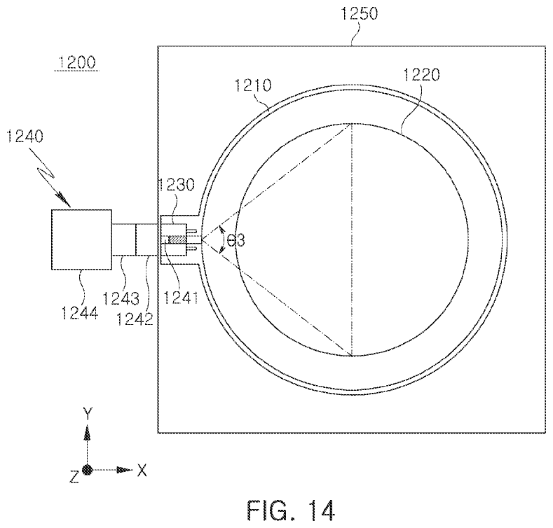

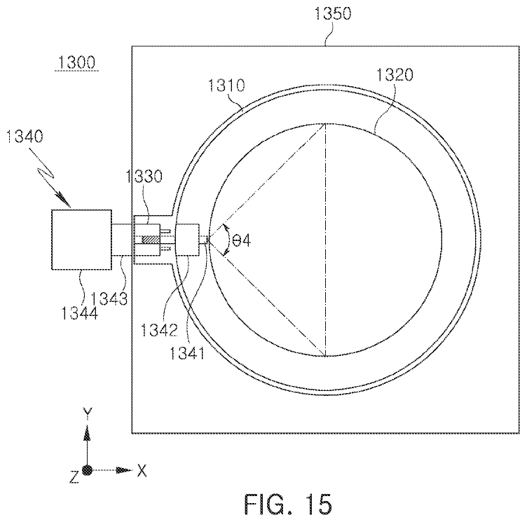

According to example implementations illustrated in FIGS. 14 and 15, the optical units 1242 and 1342 may include collimation lenses, and specific example implementations of the collimation lenses may be similar to those described in FIGS. 9 to 11. The plasma diagnostic device 1240 illustrated in FIG. 14 may be disposed outside the chamber wall 1210 and have a third angle of view θ3. In the case of the plasma diagnostic device 1340 illustrated in FIG. 15, the pinhole unit 1341 and the optical unit 1342 may be disposed inside the chamber wall 1310, and the filter unit 1343 and the sensor unit 1344 may be disposed outside the chamber wall 1310. In this case, the plasma diagnostic device 1340 may have a fourth angle of view θ4. Unlike FIG. 14, since the pinhole unit 1341 of FIG. 15 may not be interfered by the view port 1330 and the chamber wall 1310, the fourth angle of view θ4 may be wider than the third angle of view θ3. Accordingly, the diagnostic accuracy of the plasma diagnostic device 1340 of FIG. 15 may be higher than that of the plasma diagnostic device 1240 of FIG. 14.

Comparing the field of view and the plasma diagnosis accuracy according to the implementations illustrated in FIGS. 12 to 15, in the order of the first angle of view θ1, the second angle of view θ2, the third angle of view θ3 and the fourth angle of view θ4, the angle of view may get wider and wider, and the plasma diagnosis accuracy thereof may be increased in the order thereof.

According to example implementations illustrated in FIGS. 16 and 17, the optical units 1452, 1462, 1552, and 1562 may include collimation lenses, and specific example implementations of the collimation lenses may be similar to those described in FIGS. 9 to 11. Unlike FIGS. 14 and 15, one chamber wall 1410 or 1510 may include two view ports 1430 and 1440, or 1530 and 1540, respectively, to install two plasma diagnostic devices 1450 and 1460, or 1550 and 1560 therein. However, the number of view ports and plasma diagnostic device may not be limited thereto.

According to an example implementation illustrated in FIG. 16, the semiconductor process monitoring equipment 1400 may include a first view port 1430 and a second view port 1440, and may include first plasma diagnostic device 1450 installed in the first view port 1430 and second plasma diagnostic device 1460 installed in the second view port 1440. Each of the first plasma diagnostic device 1450 and the second plasma diagnostic device 1460 may have a fifth angle of view θ5, and the fifth angle of view θ5 may be identical to the third angle of view θ3 in FIG. 14. Furthermore, the first view port 1430 may disposed in a first direction (X-axis direction in FIG. 16) from a center axis of the chamber, and the second view port 1440 may be disposed in a second direction (Y-axis direction in FIG. 16), orthogonal to the first direction.

According to an example implementation illustrated in FIG. 17, the semiconductor process monitoring equipment 1500 may include a first view port 1530 and a second view port 1540, and may include first plasma diagnostic device 1550 installed in the first view port 1530 and second plasma diagnostic device 1560 installed in the second view port 1540. Each of the first plasma diagnostic device 1550 and the second plasma diagnostic device 1560 may have a sixth angle of view θ6, and the sixth angle of view θ6 may be identical to the third angle of view θ3 in FIG. 14. Furthermore, each of the first view port 1530 and the second view port 1540 may be disposed in a first direction (X-axis direction in FIG. 17) from the center axis of the chamber.

The semiconductor process monitoring equipment 1400 and the semiconductor process monitoring equipment 1500 according to example implementations of FIGS. 16 and 17 are equipped with two plasma diagnostic devices 1450 and 1460 and two plasma diagnostic devices 1550 and 1560, respectively, and each of the plasma diagnostic devices 1450, 1460, 1550 and 1560 has the same angle of view as that of the plasma diagnostic device 1240 of FIG. 14. In other words, a surface area of the wafers 1420 and 1520 that can be measured by the semiconductor process monitoring equipment 1400 and 1500 illustrated in FIGS. 16 and 17 is larger than that of the wafer 1220 that can be measured by the semiconductor process monitoring equipment 1200 illustrated in FIG. 14. Accordingly, the diagnostic accuracy of the semiconductor process monitoring equipment 1400 and 1500 illustrated in FIGS. 16 and 17 may be higher than that of the semiconductor process monitoring equipment 1200 illustrated in FIG. 14.

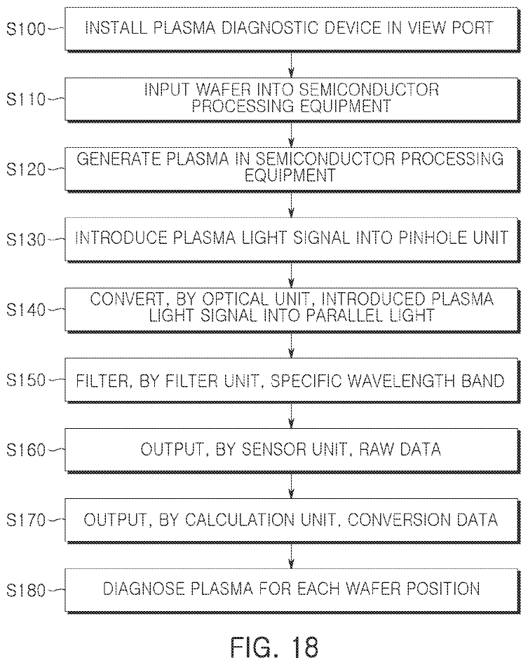

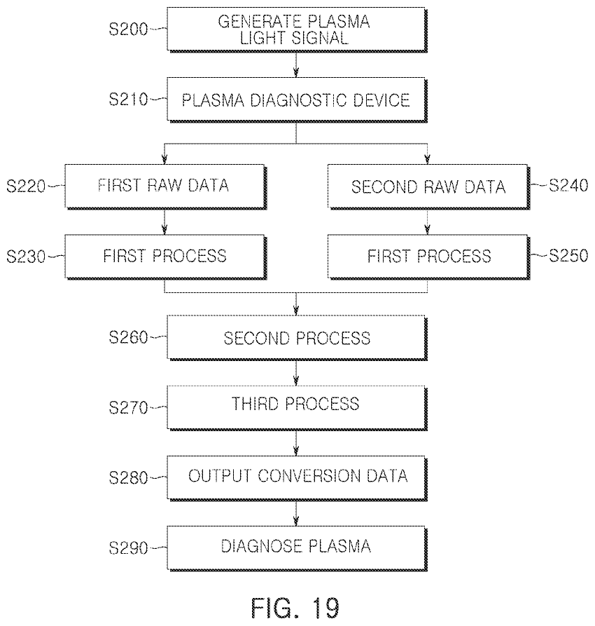

FIG. 18 is a flowchart illustrating an example of a plasma diagnosis process.

Plasma diagnostic device is installed in a view port (S100). The view port may be formed on one side of a chamber wall, and at least one view port is formed. The plasma diagnostic device may be installed inside or outside the view port in a direction oriented toward a central portion of a chamber.

A wafer is input into semiconductor processing equipment (S110). In this case, the plasma diagnostic device may be transferred by a FOUP and may be put into the semiconductor processing equipment. In this case, the plasma diagnostic device passes through wafer transfer equipment and a load lock chamber of a semiconductor processing system. The plasma diagnostic device may be fixed onto an electrostatic chuck inside the semiconductor processing equipment.

Then, plasma is generated inside the semiconductor processing equipment (S120), and specifically, the plasma is generated inside a chamber included in the semiconductor processing equipment. While a gas supply unit supplies at least one of the source gas and the reaction gas to a space inside the chamber, a power supply unit supplies power to an electrode installed in the space inside the chamber. Due to the supplied power, the source gas or the reaction gas collides as it is accelerated to electric energy in the space inside the chamber, and a chain reaction then occurs to generate the plasma.

When the plasma is generated, a plasma light signal may be generated in the process of absorbing and emitting energy. Since the plasma light signal may be more effectively scattered at specific wavelengths depending on plasma distribution, the plasma distribution may be diagnosed by analyzing a specific wavelength band of the plasma light signal.

When the plasma light signal is introduced into a pinhole unit (S130), the optical unit converts the introduced plasma light signal into parallel light (S140). In other words, the plasma light signal may be incident on a filter unit perpendicularly to the filter unit. Accordingly, an incidence angle of the plasma light signal on the filter unit may be maintained at a value close to verticality, thereby improving the accuracy of filtering a specific wavelength band in the filter unit as well as improving the diagnostic performance of the plasma diagnostic device. For example, the optical unit may include an off-axis parabolic mirror or a collimation lens, and the optical unit may further include a relay lens and/or a plane mirror.

An output of the optical unit is vertically incident on the filter unit, and the filter unit filters a specific wavelength band (S150). A plasma light signal at a specific wavelength band from the filter unit is incident on a sensor unit, and the sensor unit outputs raw data using the signal (S160). In some implementations, based on a first direction, parallel to an upper surface of the wafer, the raw data may indicate the distribution of the plasma light signal for each position in a direction, perpendicular to the upper surface of the wafer.

A calculation unit receives the raw data from the sensor unit. The calculation unit outputs conversion data as a result of calculating raw data (S170). In this case, the calculation unit uses the Abel Transformation or the PT Transformation. In some implementations, based on a first direction, parallel to an upper surface of the wafer, the conversion data may indicate the distribution of plasma for each position in a second direction, parallel to the upper surface of the wafer and perpendicular to the first direction.

Accordingly, the plasma for each wafer position is diagnosed through the conversion data (S180), and for example, the plasma distribution for each wafer position is diagnosed. By controlling the semiconductor processing equipment using the plasma distribution diagnosis results, the distribution of the semiconductor process may be improved, or the yield of the semiconductor process may be improved. Furthermore, the plasma distribution is continuously monitored during the semiconductor process, thereby allowing for more accurate determination of when the semiconductor process terminates. If necessary, the conversion data is used to interrupt the semiconductor process, or a corresponding wafer is treated as defective so that no subsequent processes may be performed, thereby improving the yield of the semiconductor process.

FIG. 19 is a flowchart illustrating another example of a plasma diagnosis process.

Plasma diagnostic device may be installed in a view port in a center direction of the chamber. A wafer may be introduced into semiconductor processing equipment, and the wafer may be disposed on a wafer support. Then, plasma may be generated inside the semiconductor processing equipment. When plasma is generated, a plasma light signal is generated in the process of absorbing and emitting energy (S200).

The plasma light signal is introduced into the plasma diagnostic device (S210). The plasma diagnostic device may include a pinhole unit, an optical unit, a filter unit, and a sensor unit, and the plasma optical signal may be divided into a first optical signal, a second optical signal, and a third optical signal.

The plasma optical signal may be introduced into the pinhole unit, and the pinhole unit may emit the first optical signal naturally dispersed from an end of the pinhole unit to the optical unit. The optical unit may emit the second optical signal obtained by converting the first optical signal into parallel light, and the filter unit may emit the third optical signal obtained by filtering a specific wavelength band of the second optical signal. The sensor unit may transmit raw data obtained by capturing the third optical signal to a calculation unit connected to the plasma diagnostic device.

The filter unit may filter the second optical signal into one or more specific wavelength bands. In other words, as the filter unit filters the second optical signal into one or more specific wavelength bands, the sensor unit can output one or more raw data. In some implementations, the sensor unit may include an image sensor, and the raw data may be an image indicative of the distribution of the plasma light signal for each position. Specifically, based on the first direction, parallel to an upper surface of the wafer, the distribution of the plasma light signal for each position may be displayed in a direction, perpendicular to the upper surface of the wafer.

In some implementations, the raw data may include first raw data and second raw data, but the present disclosure is not limited thereto. The first raw data may be data about a second optical signal filtered by a first specific wavelength band in the filter unit, and the second raw data may be data about a second optical signal filtered by a second specific wavelength band by the filter unit. In some implementations, the second raw data may be generated after first raw data is generated. In other words, the plasma diagnostic device outputs the second raw data (S240) after outputting the first raw data (S220).

The calculation unit may receive raw data from the plasma diagnostic device and diagnose plasma using the raw data. In some implementations, the calculation unit diagnoses plasma using the first raw data and the second raw data. The calculation unit performs a first process (S230 and S250), a second process (S260), and a third process (S270) on the raw data, and outputs conversion data that has undergone all the first to third processes. (S280).

The calculation unit performs the first process on each raw data (S230 and S250). In some implementations, the calculation unit first receives the first raw data from the plasma diagnostic device to initiate the first process for the first raw data (S230), and then receives the second raw data to initiate the first process for the second raw data (S250).

The first process is a process of removing dark noise from the raw data. In some implementations, the raw data may be an image indicative of plasma light distribution. The image may include the dark noise generated by high temperature environments inside a chamber, and the dark noise may impedes the accuracy of analysis using the image. The calculation unit may improve plasma diagnosis accuracy, by performing the first process of removing the dark noise of each of the first raw data and the second raw data (S230 and S250).

The second process is a process of removing random noise (S260). The calculation unit may perform the second process using both the first and second raw data that have undergone the first process. In other words, the first process may be performed on each raw data, but the second process may be performed at once using all the raw data. According to an implementation of the present disclosure, an average pixel value of the first and second raw data that has undergone the first process may be calculated, and the first and second raw data may be replaced with the average pixel value, thus deriving one raw data. In other words, one image may be derived through the second process. However, one image may include the random noise generated by characteristics of sensors and plasma. Accordingly, the plasma diagnosis accuracy may be improved by removing the random noise through the second process.

The third process is a process of performing flat-field correction on the raw data that has undergone the second process (S270). According to an implementation of the present disclosure, one image that has undergone the second process may include differences in characteristics between the first and second raw data. For example, the type or number of devices included in each wafer area may be different, and in this case, differences in plasma characteristics may occur for each wafer area. Accordingly, one image that has undergone the second process may include deviations between wafer areas. Accordingly, the diagnosis accuracy may be improved by offsetting a deviation for each wafer area.

The calculation unit outputs conversion data using the output that has undergone the third process (S280), and diagnoses the plasma using the conversion data (S290). For example, Abel transformation or PT transformation may be applied to an output that has undergone the third process. According to an implementation of the present disclosure, based on a first direction, parallel to an upper surface of the wafer, the conversion data may indicate the distribution of plasma for each wafer position in a second direction, parallel to the upper surface of the wafer and perpendicular to the first direction.

During the semiconductor process, the plasma distribution may be continuously monitored using the conversion data, thereby allowing for more accurate determination of when the semiconductor process terminates. Furthermore, the conversion data may be used to interrupt the semiconductor process, or a corresponding wafer may be treated as defective so that no subsequent processes may be performed, thereby improving the yield of the semiconductor process.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

The present disclosure is not limited to the above-described implementations and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. Semiconductor processing equipment comprising:
a chamber including a chamber wall and a wafer support on which the wafer is disposed;
at least one view port installed on the chamber wall; and
at least one plasma diagnostic device installed in the at least one view port in a center direction of the chamber,
wherein the at least one plasma diagnostic device includes a pinhole through which a first optical signal passes, wherein the first optical signal is naturally dispersed from an end of the pinhole,
an optical device in which the first optical signal is incident, wherein the optical device is configured to convert the first optical signal into a second optical signal which is parallel light, and to emit the second optical signal,
a filter configured to filter the second optical signal and to output a third optical signal of a specific wavelength band, and
a sensor configured to monitor a distribution of the first optical signal, the second optical signal, and the third optical signal.

2. Semiconductor processing equipment of claim 1, wherein the optical device includes an off-axis-parabolic mirror.

3. Semiconductor processing equipment of claim 2, wherein the optical device includes a plane mirror that reflects the second optical signal reflected by the off-axis-parabolic mirror to change a movement direction of the second optical signal.

4. Semiconductor processing equipment of claim 3, wherein the optical device includes a relay lens that extends a movement distance of the second optical signal.

5. Semiconductor processing equipment of claim 4, wherein the relay lens includes a first lens and a second lens,
wherein the second optical signal passing through the first lens is collected at a convergence point and then incident on the second lens, and the second optical signal passing through the second lens is parallel light, and
wherein the plane mirror is disposed at the convergence point to change the movement direction of the second optical signal.

6. Semiconductor processing equipment of claim 1, wherein the optical device includes a collimation lens.

7. Semiconductor processing equipment of claim 6, wherein the optical device includes a relay lens that extends a movement distance of the second optical signal.

8. Semiconductor processing equipment of claim 7, wherein the relay lens includes a first lens and a second lens,
wherein the second optical signal passing through the first lens is collected at a convergence point and then incident on the second lens, and the second optical signal passing through the second lens is parallel light, and
wherein the optical device includes a plane mirror disposed at the convergence point to change a movement direction of the second optical signal.

9. Semiconductor processing equipment of claim 1, wherein the filter includes a narrow band pass filter.

10. Semiconductor processing equipment of claim 1, wherein the pinhole, the optical device, the filter, and the sensor are sequentially arranged.

11. Semiconductor processing equipment comprising:
a wafer;
a chamber including a chamber wall and a wafer support on which the wafer is disposed;
at least one view port installed on the chamber wall;
at least one plasma diagnostic device installed in the at least one view port in a center direction of the chamber; and
a calculation circuit connected to the at least one plasma diagnostic device,
wherein the at least one plasma diagnostic device includes a pinhole on which an optical signal is incident, an optical device configured to convert the optical signal naturally dispersed from an end of the pinhole into parallel light, a filter configured to filter a specific wavelength band of the parallel light, and a sensor, and
wherein the calculation circuit is configured to calculate an output of the sensor and to output area-specific information of plasma generated in a space inside the chamber.

12. The semiconductor processing equipment of claim 11, wherein the at least one plasma diagnostic device is installed outside the chamber wall.

13. The semiconductor processing equipment of claim 11, wherein the pinhole and the optical device are installed inside the chamber wall, and
wherein the filter and the sensor are installed outside the chamber wall.

14. The semiconductor processing equipment of claim 11, wherein the optical device includes an off-axis-parabolic mirror and a plane mirror, and the plane mirror reflects the optical signal reflected by the off-axis-parabolic mirror to change a movement direction the optical signal.

15. The semiconductor processing equipment of claim 11, wherein the optical device includes a collimation lens a relay lens that extends a movement distance of the optical signal.

16. The semiconductor processing equipment of claim 15, wherein the relay lens includes a first lens and a second lens,
wherein the optical signal passing through the first lens is collected at a convergence point and then incident on the second lens, and a movement path of the optical signal passing through the second lens is parallel, and
wherein the optical device includes a plane mirror disposed at the convergence point to change a movement direction of the optical signal.

17. The semiconductor processing equipment of claim 11, wherein the at least one view port includes a first view port and a second view port,
wherein the at least one plasma diagnostic device includes a first plasma diagnostic device installed in the first view port and a second plasma diagnostic device installed in the second view port, and
wherein the first view port is disposed in a first direction from a center axis of the chamber, and the second view port is disposed in a second direction perpendicular to the first direction.

18. The semiconductor processing equipment of claim 11, wherein the at least one view port includes a first view port and a second view port,
wherein the at least one plasma diagnostic device includes a first plasma diagnostic device installed in the first view port and a second plasma diagnostic device installed in the second view port, and
wherein each view port of the first view port and the second view port is disposed in a first direction from a center axis of the chamber.

19. Semiconductor processing equipment comprising:
a wafer;
a chamber including a chamber wall and a wafer support on which the wafer is disposed;
at least one view port installed on the chamber wall;
at least one plasma diagnostic device installed in the at least one view port in a center direction of the chamber; and
a calculation circuit connected to the at least one plasma diagnostic device,
wherein the at least one plasma diagnostic device includes a pinhole, an optical device, a filter, and a sensor,
wherein the pinhole is configured to emit a first optical signal to the optical device, the optical device is configured to convert the first optical signal into parallel light and to emit the parallel light as a second optical signal, the filter is configured to filter a specific wavelength band of the second optical signal to emit a third optical signal, and the sensor is configured to capture the third optical signal to obtain raw data and to transmit the raw data to the calculation circuit,
wherein the raw data includes first raw data obtained by filtering a first specific wavelength band of the second optical signal by the filter and second raw data obtained by filtering a second specific wavelength band of the second optical signal by the filter, and
wherein the calculation circuit is configured to use the first raw data and the second raw data to diagnose plasma.

20. The semiconductor processing equipment of claim 19, wherein the calculation circuit is configured to,
perform a first process of removing dark noise of each raw data of the first raw data and the second raw data,
perform a second process of replacing the first raw data and the second raw data with an average pixel value and removing random noise,
perform a third process of performing flat-field correction of the first raw data and the second raw data, and
output conversion data that has undergone the first process, the second process, and the third process.
